(19) United States
(12) Patent Application Publication
(10) Pub. No.: US 2017/0158571 A1
(43) Pub. Date: Jun. 8, 2017

(54) FERROELECTRIC CERAMICS AND MANUFACTURING METHOD OF SAME

(71) Applicant: YOUTEC CO., LTD., Chiba (JP)

(72) Inventor: Takeshi KIJIMA, Chiba (JP)

(73) Assignee: YOUTEC CO., LTD., Chiba (JP)

(21) Appl. No.: 15/325,592

(22) PCT Filed: Apr. 27, 2015
(86) PCT No.: PCT/JP2015/062647

§ 371 Date: Jan. 11, 2017

(30) Foreign Application Priority Data
Jul. 16, 2014 (JP) 2014-146250

(51) Int. Cl. C04B 41/50; C04B 35/472; C04B 35/622; H01L 41/39; C04B 41/87; H01L 41/047; H01L 41/187; C04B 35/491; C04B 41/00

(52) U.S. Cl. CPC C04B 41/5041; C04B 35/491; C04B 35/472; C04B 35/62218; C04B 41/009; C04B 41/87; H01L 41/0478; H01L 41/1876; H01L 41/39; C04B 2235/3296; C04B 2235/3249; C04B 2235/3234; C04B 2235/768

(57) ABSTRACT

To improve a piezoelectric property. One aspect of the present invention is ferroelectric ceramics including: a Pb(Zr_{1-A}Ti_{A})O₃ film; and a Pb(Zr₁₋ₓTiₓ)O₃ film formed on the Pb(Zr_{1-A}Ti_{A})O₃ film; wherein the A and x satisfy the following Formulae 1 to 3:

0≦A≦0.1 Formula 1

0.1<x<1 Formula 2

A<x Formula 3.

### TECHNICAL FIELD

The present invention relates to ferroelectric ceramics and a manufacturing method of the same.

### BACKGROUND ART

There will be explained a conventional manufacturing method of Pb(Zr,Ti)O₃ (hereinafter, referred to as “PZT”) perovskite-type ferroelectric ceramics.

A SiO₂ film having a thickness of 300 nm is formed on a 4-inch Si wafer, and a TiOₓ film having a thickness of 5 nm is formed on the SiO₂ film. Next, a Pt film having a thickness of 150 nm oriented in, for example, (111) is formed on the TiOₓ film, and a PZT sol-gel solution is rotation-coated on the Pt film by a spin coater. The spinning condition at this time is a condition in which rotation is made at a rotation speed of 1500 rpm for 30 seconds, and rotation is made at a rotation speed of 4000 rpm for 10 seconds.

Next, the PZT sol-gel solution coated is heated and kept on a hot plate at 250° C. for 30 seconds for drying, and after removal of the water content, the resulting material is further heated and kept on a hot plate at a high temperature of 500° C. for 60 seconds for pre-calcining. A PZT amorphous film having a thickness of 150 nm is produced by repetition of such operations several times.

Subsequently, the PZT amorphous film is subjected to an annealing treatment at 700° C. by use of a pressurized-lamp annealing apparatus (RTA: rapidly thermal anneal) for crystallization of PZT. The PZT film thus crystallized has a perovskite structure (refer to, for example, Patent Literature 1).

### CITATION LIST

### Patent Literature

[Patent Literature 1] WO 2006/087777

### SUMMARY OF INVENTION

### Technical Problem

An object of one aspect of the present invention is to improve a piezoelectric property.

### Solution to Problem

Hereinafter, various aspects of the present invention will be described.

[1] Ferroelectric ceramics including:

a Pb(Zr_{1-A}Ti_{A})O₃ film; and

a Pb(Zr₁₋ₓTiₓ)O₃ film formed on the Pb(Zr_{1-A}Ti_{A})O₃ film, wherein

the A and x satisfy the following Formulae 1 to 3:

0≦A≦0.1 Formula 1

0.1<x<1 Formula 2

A<x Formula 3.

Note that the Pb(Zr₁₋ₓTiₓ)O₃ film is oriented in (001)

[2] The ferroelectric ceramics according to [1] above, wherein

the A is 0, and

the Pb(Zr_{1-A}Ti_{A})O₃ film is a PbZrO₃ film.

Note that the Pb(Zr₁₋ₓTiₓ)O₃ film is oriented in (001).

[3] The ferroelectric ceramics according to [1] or [2] above, wherein

the Pb(Zr_{1-A}Ti_{A})O₃ film is formed on an oxide film.

Note that the oxide film is preferably made of an oxide having a perovskite structure.

[4] The ferroelectric ceramics according to [3] above, wherein

the oxide film is a Sr(Ti,Ru)O₃ film.

Note that the Sr(Ti,Ru)O₃ film is preferably a Sr(Ti₁₋ₓRuₓ)O₃ film, and the x satisfies the following Formula 4:

0.01≦x≦0.4 Formula 4.

[5] The ferroelectric ceramics according to any one of [1] to [4] above, wherein

the Pb(Zr_{1-A}Ti_{A})O₃ film is formed on an electrode film.

[6] The ferroelectric ceramics according to [5] above, wherein

the electrode film is made of an oxide or a metal.

Note that the oxide may correspond to a Sr(Ti₁₋ₓRuₓ)O₃ film, and the x satisfies the following Formula 4:

0.01≦x≦0.4 Formula 4.

[7] The ferroelectric ceramics according to [5] or [6] above, wherein

the electrode film is a Pt film or an Ir film.

Note that the Pt film is oriented in (100).

[8] The ferroelectric ceramics according to any one of [5] to [7] above, wherein

the electrode film is formed on a ZrO₂ film.

Note that the ZrO₂ film is oriented in (100).

[9] The ferroelectric ceramics according to any one of [5] to [8] above, wherein

the electrode film is formed on a Si substrate.

Note that the Si substrate is oriented in (100).

[10] A manufacturing method of ferroelectric ceramics, including forming a Pb(Zr₁₋ₓTiₓ)O₃ film on a Pb(Zr_{1-A}Ti_{A})O₃ film, wherein

the A and x satisfy the following Formulae 1 to 3:

0≦A≦0.1 Formula 1

0.1<x<1 Formula 2

A<x Formula 3.

Note that the Pb(Zr₁₋ₓTiₓ)O₃ film is oriented in (001).

[11] The manufacturing method of ferroelectric ceramics according to [10] above, wherein

the A is 0, and

the Pb(Zr_{1-A}Ti_{A})O₃ film is a PbZrO₃ film.

Note that the Pb(Zr₁₋ₓTiₓ)O₃ film is oriented in (001)

[12] The manufacturing method of ferroelectric ceramics according to [10] or [11] above, wherein

the Pb(Zr_{1-A}Ti_{A})O₃ film is formed by coating a Pb(Zr_{1-A}Ti_{A})O₃ precursor solution on a substrate, and performing crystallization in an oxygen atmosphere at 5 atm or more (preferably 7.5 atm or more).

Note that, in the aforementioned various aspects of the present invention, when forming the particular C (hereinafter, referred to as “C”) on (or under) the particular B (hereinafter, referred to as “B”) (C being formed), the present invention is not limited to the case of forming C directly on (or under) B (C being formed), but also includes the case of forming C via other matter on (or under) B (C being formed) within the scope not inhibiting the effects of one aspect of the present invention.

### Advantageous Effects of Invention

The piezoelectric property can be improved by application of one aspect of the present invention.

### BRIEF DESCRIPTION OF DRAWINGS

FIG. 1 is a schematic cross-sectional view explaining a manufacturing method of ferroelectric ceramics according to one aspect of the present invention.

FIG. 2 is a schematic cross-sectional view explaining a manufacturing method of ferroelectric ceramics according to one aspect of the present invention.

FIGS. 3A to 3C are each a cross-sectional view for explaining a manufacturing method of a sample according to Example 1.

FIG. 4 is an XRD (X-Ray Diffraction) chart of a sample where the deposition of films up to a Pt film 13 illustrated in FIG. 3A, according to Example 1, is completed.

FIG. 5 is a chart illustrating the XRD diffraction result of a sample illustrated in FIG. 3A.

FIG. 6 is a chart illustrating the XRD diffraction result of a sample illustrated in FIG. 3C.

FIG. 7 is a chart illustrating the XRD diffraction result of a PZT film sample as a comparative Example in which (400) orientation and (004) orientation are mixed.

FIG. 8 is a cross-sectional view for explaining a manufacturing method of a sample according to Example 2.

FIG. 9 is a cross-sectional view for explaining a manufacturing method of a sample according to Comparative Example.

FIG. 10 is an XRD chart of Sample 4 (Example).

FIG. 11 is an XRD chart of Sample 6 (Example).

FIG. 12 is an XRD chart of Sample 9 (Comparative Example).

FIG. 13 is an XRD chart of Sample 1 (Example).

FIG. 14 is an XRD chart of Sample 2 (Example).

FIG. 15 is an XRD chart of Sample 3 (Example).

FIG. 16 is an XRD chart of Sample 4 (Example).

FIG. 17 is an XRD chart of Sample 5 (Example).

FIG. 18 is an XRD chart of Sample 6 (Example).

FIG. 19 is a diagram for explaining the full width at half maximum (FWHM).

FIG. 20 is an XRD chart of Sample 7 (Comparative Example).

FIG. 21 is an XRD chart of Sample 8 (Comparative Example).

FIG. 22 is an XRD chart of Sample 9 (Comparative Example).

FIG. 23 is a view illustrating the crystal structure of PZO being orthorhombic.

FIG. 24A illustrates an XRD pattern of a PZT film according to Example 3, and FIG. 24B illustrates an XRD pattern of a PZO film according to Example 3.

### DESCRIPTION OF EMBODIMENTS

Hereinafter, embodiments and examples of the present invention will be explained in detail by use of the drawings. However, a person skilled in the art would be able to easily understand that the present invention is not limited to the following explanation but the form and details thereof can be variously changed without deviating from the gist and the scope of the present invention. Accordingly, the present invention should not be construed as being limited to the description of the present embodiments and examples shown below.

### First Embodiment

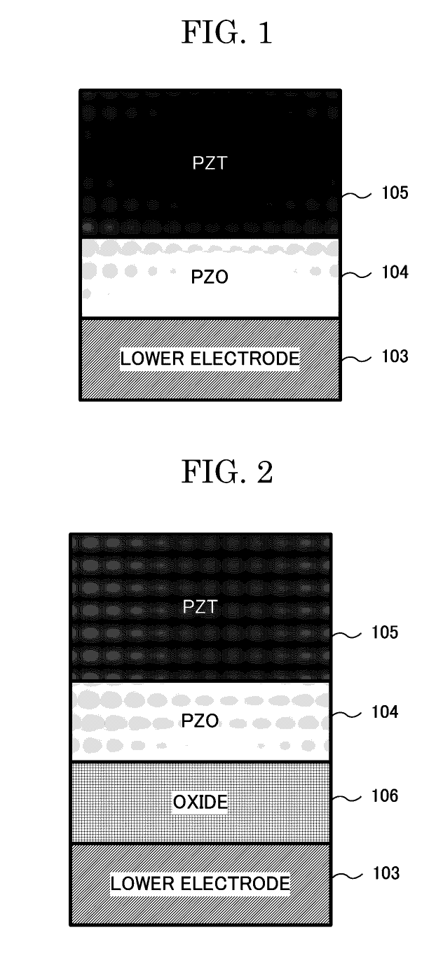

FIG. 1 is a schematic cross-sectional view for explaining a manufacturing method of ferroelectric ceramics according to one aspect of the present invention.

A substrate (not illustrated) is prepared. Various substrates can be used as such a substrate, and for example, there can be used: a single crystal substrate of a Si single crystal, a sapphire single crystal or the like; a single crystal substrate formed with a metal oxide film on the surface thereof; a substrate formed with a polysilicon film, or a silicide film on the surface thereof; or the like. Note that, in the present embodiment, a Si substrate oriented in (100) is used.

Next, a ZrO₂ film (not illustrated) is formed on the Si substrate (not illustrated) at a temperature of 550° C. or less (preferably a temperature of 500° C.) by a vapor deposition method. The ZrO₂ film is oriented in (100). Note that, when the ZrO₂ film is formed at a temperature of 750° C. or more by a vapor deposition method, the ZrO₂ film is not oriented in (100).

In the present description, orientation in (100), orientation in (200) and orientation in (400) are substantially the same, and also orientation in (001), orientation in (002) and orientation in (004) are substantially the same.

Thereafter, a lower electrode 103 is formed on the ZrO₂ film. The lower electrode 103 is formed of an electrode film made of a metal or an oxide. For example, a Pt film or an Ir film is used as the electrode film made of a metal. For example, a Sr(Ti₁₋ₓRuₓ)O₃ film is used as the electrode film made of an oxide, and x satisfies the following Formula 4.

0.01≦x≦0.4 Formula 4

In the present embodiment, there is formed as the lower electrode, on the ZrO₂ film, a Pt film 103 through epitaxial growth by sputtering at a temperature of 550° C. or less (preferably a temperature of 400° C.). The Pt film 103 is oriented in (200).

Next, a PbZrO₃ film (hereinafter, also referred to as “PZO film”) 104 is formed on the lower electrode 103. The PZO film 104 can be formed by various methods, and for example, can be formed by a sol-gel method, a CVD method or a sputtering method. In a case where the PZO film 104 is formed by a sol-gel method, a PZO precursor solution may be coated on the substrate and subjected to crystallization in an oxygen atmosphere at 5 atm or more (preferably 7.5 atm or more). Note that the respective lattice constants of PZO are as follows: a=8.232 angstroms, b=11.776 angstroms and c=5.882 angstroms. The length along the a-axis is approximately twice the average perovskite (ap≈4 angstroms), the length along the c-axis is represented by c≈(√2)ap, and the length along the b-axis is represented by b≈2c. Such changes in the lattice constants of PZO are essentially achieved by allowing the period in the b-axis direction to be doubled, due to the rotation of a perovskite octahedral crystal and also the distortion of an octahedron added thereto.

PZO is orthorhombic crystal as illustrated in FIG. 23. Therefore, PZO has apparently large lattice constants. The reason is that the perovskite is longitudinally rotated by approximately 45° and is handled like so a large crystal as if the circumference of the rotated crystal is surrounded by a dot line portion. Namely, an orthorhombic crystal is conventionally handled as if the crystal has apparently very long a, b and c-axes. Actual PZO is a crystal illustrated by a solid line, and is an ordinary perovskite crystal.

Next, a PZT film 105 is formed on the PZO film 104. The PZT film 105 is a Pb(Zr₁₋ₓTiₓ)O₃ film, and x satisfies the following Formula 2′. The Pb(Zr₁₋ₓTiₓ)O₃ film is oriented in (001).

0<x<1 Formula 2′

Note that the “PZT film” also includes Pb(Zr,Ti)O₃ containing impurities, and may contain various impurities as long as the function as the piezoelectric body of the PZT film is not eliminated even if such impurities are contained.

Hereinafter, one example of the method for forming the PZT film will be explained in detail.

There was used, as the sol-gel solution for PZT film formation, an E1 solution having a concentration of 10% by weight, in which butanol was used as a solvent and lead was added in an amount insufficient by 70% to 90%.

An alkali alcohol having an amino group, referred to as dimethylaminoethanol, was added to the sol-gel solution in a volume ratio of E1 sol-gel solution:dimethylaminoethanol=7:3; and thus the resultant substance exhibited a strong alkalinity of pH 12.

A PZT amorphous film was formed by spin-coating through the use of the present solution as described above. MS-A200 manufactured by MIKASA CO., LTD. was used as the spin coater. First, rotation was made at 800 rpm for 5 seconds and then at 1500 rpm for 10 seconds, then rotation was gradually increased to 3000 rpm for 10 seconds, and subsequently the resultant substance was left to stand on a hot plate (ceramic hot plate AHS-300 manufactured by AS ONE Corporation) at 150° C. for 5 minutes in the atmosphere and thereafter left to stand on the hot plate (the same AHS-300) at 300° C. for 10 minutes in the atmosphere again, and then cooled to room temperature. Such operations were repeated five times to thereby form a PZT amorphous film having a desired thickness of 200 nm, on the PZO film 104. A plurality of such films was produced.

Next, the above PZT amorphous film is heat-treated in a pressurized oxygen atmosphere to thereby allow a PZT film 105, in which the PZT amorphous film is crystallized, to be formed on the PZO film 104. Note that one example of the lattice constants of PZT is 0.401 nm.

After the PZT film 105 is formed as described above, the PZT film 105 may be subjected to a poling treatment.

Note that, although the PZT film 105 is formed by a sol-gel method in the present embodiment, the PZT film may also be formed by a sputtering method.

According to the present embodiment, it is possible to improve a piezoelectric property of the PZT film 105 by the use of the PZO film 104 as an initial nuclear layer (namely, buffer layer) of the PZT film 105. According to a detailed explanation, although PbZrO₃ (PZO) is anti-ferroelectric in a case where the Ti ratio is 0 (zero) in the phase diagram of Pb(Zr₁₋ₓTiₓ)O₃ (PZT), PZO has the longest length of c-axis among Pb(Zr₁₋ₓTiₓ)O₃, and thus PZO works in a direction in which the length of c-axis of the whole PZT is extended, with the result that the maximum piezoelectric performance which the structure can have can be easily obtained. Namely, the entire PZT is affected by the crystal axis of the PZO initial nucleus by setting PZO as an initial nucleus, and thus the c-crystal axis becomes easily extended over the entire PZT film, namely, becomes easily polarized, with the result that piezoelectricity can be easily achieved.

Note that, in the present embodiment, although the PZO film 104 in which the Ti ratio is 0 in the phase diagram of Pb(Zr,Ti)O₃ is formed on the lower electrode 103 and the Pb(Zr₁₋ₓTiₓ)O₃ film 105 (0<x<1 . . . Formula 2′) is formed on the PZO film 104, the Pb(Zr₁₋ₓTiₓ)O₃ film may also be formed on a Pb(Zr_{1-A}Ti_{A})O₃ film in which the Ti ratio is extremely low. Provided that, A and x satisfy the following Formulae 1 to 3. The Pb(Zr₁₋ₓTiₓ)O₃ film is oriented in (001).

0≦A≦0.1 Formula 1

0.1<x<1 Formula 2

A<x Formula 3

Formula 1 above can be satisfied, namely, the Ti ratio can be 10% or less, and thus the Pb(Zr_{1-A}Ti_{A})O₃ film used as the initial nucleus serves as PZT (namely, PZT in an orthorhombic crystal region (ortho-region) in the phase diagram of Pb(Zr,Ti)O₃) in an anti-ferroelectric orthorhombic crystal phase, and Pb(Zr_{1-A}Ti_{A})O₃ works in a direction in which the length of c-axis of all Pb(Zr₁₋ₓTiₓ)O₃ (PZT) is extended, with the result that the similar effect to that of the above embodiment can be obtained.

### Second Embodiment

FIG. 2 is a schematic cross-sectional view for explaining a manufacturing method of ferroelectric ceramics according to one aspect of the present invention, and the same symbols are attached to the same elements as in FIG. 1.

Layers up to a Si substrate (not illustrated), a ZrO₂ film (not illustrated) and a lower electrode 103 are formed by the similar methods to those in the first embodiment, and thus the explanation thereof is omitted.

Next, an oxide film 106 is formed on the lower electrode 103. The oxide film 106 may be made of an oxide having a perovskite structure, and is, for example, a Sr(Ti,Ru)O₃ film. The Sr(Ti,Ru)O₃ film is a Sr(Ti₁₋ₓRuₓ)O₃ film, where x satisfies the following Formula 4; and is formed by sputtering. A sintered body of Sr(Ti₁₋ₓRuₓ)O₃ at this time is used as the sputtering target. Provided that, x satisfies the following Formula 4.

0.01≦x≦0.4 (preferably 0.05≦x≦0.2) Formula 4

Note that the reason why x in the Sr(Ti₁₋ₓRuₓ)O₃ film is 0.4 or less is that, if x exceeds 0.4, the Sr(Ti₁₋ₓRuₓ)O₃ film is powdery and cannot be sufficiently solidified.

Thereafter, the Sr(Ti₁₋ₓRuₓ)O₃ film is subjected to crystallization by RTA (Rapid Thermal Anneal) in a pressurized oxygen atmosphere. The Sr(Ti₁₋ₓRuₓ)O₃ film is made of a composite oxide of strontium, titanium and ruthenium; and the composite oxide is a compound having a perovskite structure.

Next, a PZO film 104 is formed on the oxide film 106 by the similar method to that in the first embodiment. Subsequently, a PZT film 105 is formed on the PZO film 104 by the similar method to that in the first embodiment. The PZT film 105 is oriented in (001).

The similar effect to that in the first embodiment can also be achieved in the present embodiment.

Note that, although the PZO film 104 is formed on the oxide film 106 and the PZT 105 is formed on the PZO film 104 in the present embodiment, the Pb(Zr₁₋ₓTiₓ)O₃ film may also be formed on a Pb(Zr_{1-A}Ti_{A})O₃ film in which the Ti ratio is extremely low. Provided that, A and x satisfy the following Formulae 1 to 3. The Pb(Zr₁₋ₓTiₓ)O₃ film is oriented in (001).

0≦A≦0.1 Formula 1

0.1<x<1 Formula 2

A<x Formula 3

The similar effect to that in the first embodiment can be obtained by satisfaction of Formula 1.

Note that the first and second embodiments as described above may be appropriately combined and performed.

### Example 1

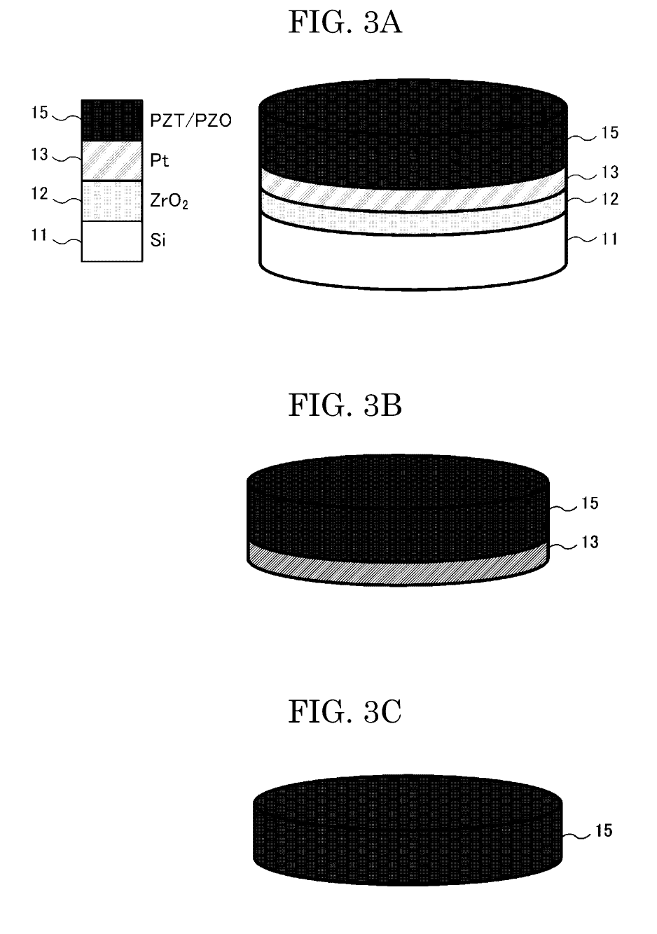

FIGS. 3A to 3C are each a cross-sectional view for explaining a manufacturing method of a sample according to Example 1.

As illustrated in FIG. 3A, a ZrO₂ film 12 was deposited on a 6-inch Si substrate 11 having a (100) crystal plane, by a reactive vapor deposition method. The vapor deposition conditions at this time are as shown in Table 1. The ZrO₂ film 12 was oriented in (100).

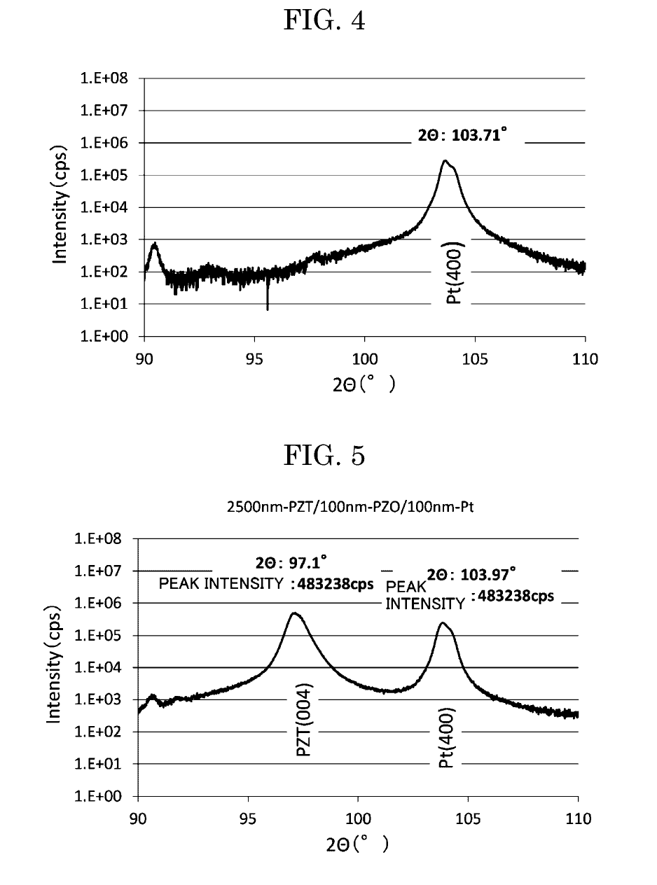

Subsequently, a Pt film 13 having a thickness of 100 nm was deposited on the ZrO₂ film 12 by sputtering. The film deposition conditions at this time are as shown in Table 1. The Pt film 13 was oriented in (200). The XRD pattern at this time is illustrated in FIG. 4.

TABLE 1
Example

| | | |
|---|---|---|
| Process | Vapor deposition | DC-sputtering |
| Depo Vac | 6.90E−03 | 3.20E−02 |
| Depo Source | Zr + O2 | Pt |
| ACC/Emission | 7.5 kV/1.50 mA | DC/100 W |
| Total Thickness (nm) | 13.4 | 100 |
| Depo Time (sec) | 930 | 720 |
| SV deg (Tsub) | 500° C. | 400° C. |
| MFC O2 | 5 sccm | Ar: 16 sccm |

FIG. 4 illustrates the XRD diffraction result of a sample in which deposition of films up to a Pt film 13 illustrated in FIG. 3A was completed. It was confirmed from the XRD chart that the Pt film was oriented in (400) and 2θ was 103.710. Note that, in FIG. 4, the vertical axis represents the intensity and the horizontal axis represents 2θ.

Next, there was formed a laminated film 15 in which a PbZrO₃ film (hereinafter, referred to as “PZO film”) and a Pb(Zr_{0.55}Ti_{0.45})O₃ film (hereinafter, referred to as “PZT film”) were sequentially laminated on the Pt film 13. Specifically, a PZO film having a thickness of 250 nm was coated on the Pt film 13 by a sol-gel method. The conditions at this time are as follows.

An MOD solution for 1.3PbZrO₃ formation (Lot. 00050667-1 manufactured by TOSHIMA Manufacturing Co., Ltd.) having a concentration of 1.4 mol/kg, ethanol and 2n-butoxyethanol were combined so that the total amount was 1000 ml (the respective substances were mixed in a ratio of 1:1:1), and 20 g of a white powder of polyvinyl pyrrolidone (K-30, NIPPON SHOKUBAI CO., LTD.) was added thereto and dissolved therein under stirring to thereby provide a raw material solution for PZO (250 nm). Three ml of the solution was dropped onto a 6-inch wafer and rotation-coated at 3000 rpm for 10 seconds, thereafter kept on a hot plate at 150° C. for 30 seconds and then kept on a hot plate at 250° C. for 90 seconds, and thereafter sintered at 600° C. in an atmosphere of 1 atm-O₂ for 3 minutes.

Subsequently, a PZT film having a thickness of 2500 nm was formed on the PZO film by a sputtering method. The sputtering conditions at this time are similar to those in Example 2. The XRD pattern at this time is illustrated in FIG. 5.

FIG. 5 is a chart illustrating the XRD diffraction result of a sample illustrated in FIG. 3A. It was confirmed from the XRD chart that the PZT film of the laminated film 15 was oriented in (004) and 2θ was 97.10. Note that, in FIG. 5, the vertical axis represents the intensity and the horizontal axis represents 2θ.

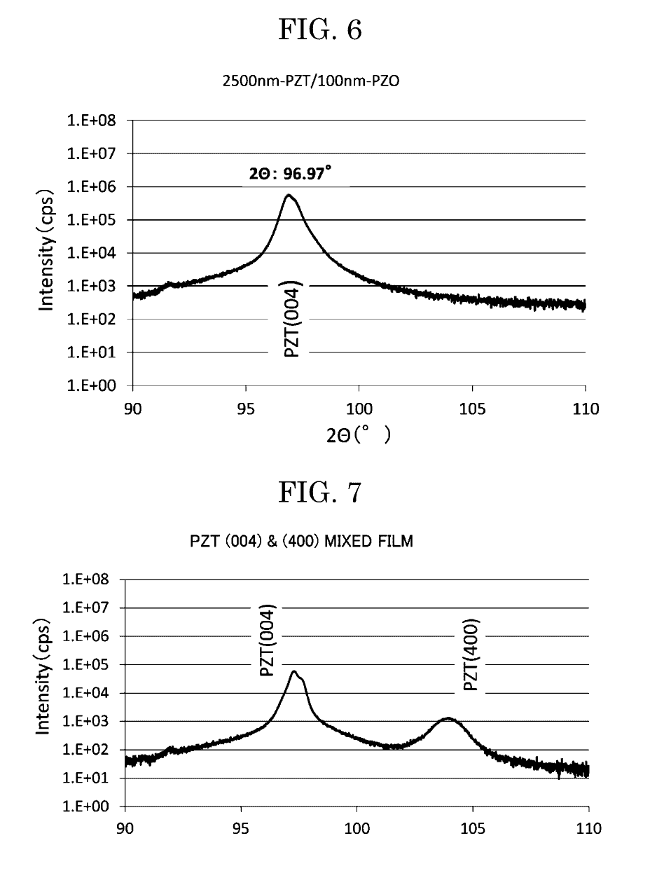

Next, the whole Si substrate 11 was cut and the ZrO₂ film 12 was removed by an ICP (Inductive Coupling Plasma) etcher as illustrated in FIG. 3B, and then the Pt film 13 was removed by milling as illustrated in FIG. 3C. Accordingly, only the laminated film 15 of PZT/PZO was left. The XRD pattern at this time is illustrated in FIG. 6.

at this time

FIG. 6 is a chart illustrating the XRD diffraction result of the sample illustrated in FIG. 3C. It was confirmed from the XRD chart that 2θ was 96.97° and only the peak of (004) was obtained with respect to the PZT film of the laminated film 15. Accordingly, it was found that the laminated film 15 of PZT/PZO was a (001) c-axis singly oriented film. Note that, in FIG. 6, the vertical axis represents the intensity and the horizontal axis represents 2θ.

Here, in a case where PZT (400) is present at the same position as in Pt (400) and the PZT film is a mixed film of (400) orientation and (004) orientation, the peak intensity of PZT (004) illustrated in FIG. 7 tends to be weaker than that of a (004) singly oriented PZT film illustrated in FIG. 6. Additionally, PZT illustrated in FIG. 7 often satisfies 2θ≧98°. Note that FIG. 7 is a chart illustrating the XRD diffraction result of a PZT film sample as Comparative Example in which (400) orientation and (004) orientation are mixed.

Naturally, in a case where the PZT film is a mixed film of PZT (400) and (004), the peak of PZT (400) illustrated in FIG. 7 is present even when a film structure of only PZT as illustrated in FIG. 3C is adopted. Accordingly, it can be said from the XRD chart illustrated in FIG. 6 that the PZT film illustrated in FIG. 3C is a (001) c-axis singly oriented film.

According to the present example, it is possible to obtain a (001) c-axis singly oriented PZT film and thus to improve a piezoelectric property of the PZT film, by the use of the PZO film 104 as the initial nuclear layer (namely, buffer layer) of the PZT film. According to a detailed explanation, PbZrO₃ (PZO) can be obtained in a case where the Ti ratio is 0 (zero) in the phase diagram of Pb(ZrₓTi₁₋ₓ)O₃ (PZT), and PZO has the longest length of c-axis among Pb(Zr₁₋ₓTiₓ)O₃, and thus PZO works in a direction in which the length of c-axis of the whole PZT is extended, thereby becoming easily polarized, with the result that piezoelectricity can be easily achieved.

### Example 2

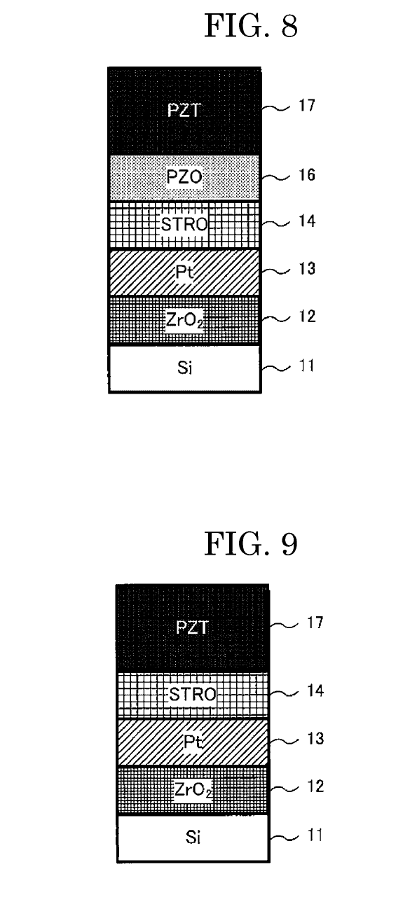

FIG. 8 is a cross-sectional view for explaining a manufacturing method of a sample according to Example 2.

A Si substrate 11, a ZrO₂ film 12 and a Pt film 13 of a sample illustrated in FIG. 8 were produced by the similar methods to those in the sample according to Example 1 illustrated in FIG. 3A.

Next, a Sr(Ti_{0.8}Ru_{0.2})O₃ film (hereinafter, referred to as “STRO film”) 14 was formed on the Pt film 13 by sputtering. The sputtering conditions at this time are as follows.

[Sputtering Conditions of STRO Film 14]

Process: RF-sputtering

Target: Sr(Ti_{0.8}Ru_{0.2})O₃

RF power: 400 W/13.56 MHz

Process pressure: 4 Pa

Gas flow rate, Ar/O₂ (sccm): 30/10

Substrate temperature: 600° C.

Process time: 20 seconds

Film thickness: 50 nm

Then, the STRO film 14 was subjected to crystallization by RTA in a pressurized oxygen atmosphere. The RTA conditions at this time are as follows.

[RTA Conditions]

Annealing temperature: 600° C.

Introduction gas: oxygen gas

Pressure: 9 kg/cm²

Temperature raising rate: 100° C./sec

Annealing time: 5 minutes

Next, a PZO film 16 having a thickness of 50 to 400 nm was deposited on the STRO film 14 by a spin-coating method. The film formation conditions at this time are as shown in the following (1) to (3).

(1) An MOD solution for 1.3PbZrO₃ formation (Lot. 00050667-1 manufactured by TOSHIMA Manufacturing Co., Ltd.) having a concentration of 1.4 mol/kg, ethanol and 2n-butoxyethanol were combined so that the total amount was 1000 ml (the respective substances were mixed in a ratio of 1:1:1), and 10 g of a white powder of polyvinyl pyrrolidone (K-30, NIPPON SHOKUBAI CO., LTD.) was added thereto and dissolved therein under stirring to thereby give a raw material solution for PZO (50 nm). Three ml of the solution was dropped onto a 6-inch wafer and rotation-coated at 5000 rpm for 10 seconds, thereafter kept on a hot plate at 150° C. for 30 seconds and then kept on a hot plate at 250° C. for 90 seconds, and subsequently sintered at 600° C. in an atmosphere of 1 atm-O₂ for 3 minutes to thereby form a PZO film having a thickness of 50 nm.

(2) An MOD solution for 1.3PbZrO₃ formation (Lot. 00050667-1 manufactured by TOSHIMA Manufacturing Co., Ltd.) having a concentration of 1.4 mol/kg, ethanol and 2n-butoxyethanol were combined so that the total amount was 1000 ml (the respective substances were mixed in a ratio of 1:1:1), and 20 g of a white powder of polyvinyl pyrrolidone (K-30, NIPPON SHOKUBAI CO., LTD.) was added thereto and dissolved therein under stirring to thereby give a raw material solution for PZO (250 nm). Three ml of the solution was dropped onto a 6-inch wafer and rotation-coated at 3000 rpm for 10 seconds, thereafter kept on a hot plate at 150° C. for 30 seconds and then kept on a hot plate at 250° C. for 90 seconds, and subsequently sintered at 600° C. in an atmosphere of 1 atm-O₂ for 3 minutes to thereby form a PZO film having a thickness of 250 nm.

(3) An MOD solution for 1.3PbZrO₃ formation (Lot. 00050667-1 manufactured by TOSHIMA Manufacturing Co., Ltd.) having a concentration of 1.4 mol/kg, ethanol and 2n-butoxyethanol were combined so that the total amount was 1000 ml (the respective substances were mixed in a ratio of 1:1:1), and 20 g of a white powder of polyvinyl pyrrolidone (K-30, NIPPON SHOKUBAI CO., LTD.) was added thereto and dissolved therein under stirring to thereby give a raw material solution for PZO (400 nm). Three ml of the solution was dropped onto a 6-inch wafer and rotation-coated at 1000 rpm for 10 seconds, thereafter kept on a hot plate at 150° C. for 30 seconds and then kept on a hot plate at 250° C. for 90 seconds, and subsequently sintered at 600° C. in an atmosphere of 1 atm-O₂ for 3 minutes to thereby form a PZO film having a thickness of 400 nm.

Next, a Pb(Zr_{0.55}Ti_{0.45})O₃ film (hereinafter, referred to as “PZT film”) 17 having a thickness of 1000 to 4000 nm was formed on the PZO film 16 by a sputtering method. The sputtering conditions at this time are as follows.

[Sputtering Conditions]

Apparatus: RF magnetron sputtering apparatus

Power: 1500 W

Gas: Ar/O₂

Pressure: 0.14 Pa

Temperature: 600° C.

Film deposition speed: 0.63 nm/sec

Film deposition time: 1.3 minutes

FIG. 9 is a cross-sectional view for explaining a manufacturing method of a sample according to Comparative Example, and the same symbols are attached to the same portions as in FIG. 8.

The sample illustrated in FIG. 9 is one obtained by removal of the PZO film 16 from the sample illustrated in FIG. 8, and has a similar film structure to that in the sample illustrated in FIG. 8, except for the PZO film 16, and the methods for forming the respective films are also similar to those in the sample.

TABLE 2
Comparison of XRD diffraction data

| | | | | | | | | Full width at |
|---|---|---|---|---|---|---|---|---|
| | | | | | | | \|(400) − | half maximum |
| | | PZT(004) | | Pt(400) | | (004)/ | (004)\| | (FWHM) |
| | Film | | Peak | | Peak | (400) | Difference in | Half-value |
| Sample | thickness | 2Θ | intensity | 2Θ | intensity | Intensity | 2θ (°) between | width |
| No. | (nm) | (°) | (cps) | (°) | (cps) | ratio (%) | lengths of axes | (°) |
| 01 | PZO: 50 | 97.17 | 122113 | 103.8 | 1182023 | 10.3 | 6.63 | 0.73 |
| 02 | PZO: 250 | 97.05 | 43533 | 104.09 | 292740 | 14.9 | 7.04 | 0.71 |
| 03 | PZO: 400 | 97.15 | 45346 | 103.92 | 276067 | 16.4 | 6.77 | 0.67 |
| 04 | 1050 | 96.86 | 170340 | 104.06 | 175807 | 96.0 | 7.20 | 0.79 |
| | (PZO: 50) | | | | | | | |
| 05 | PZT/PZO | 97.1 | 365780 | 103.96 | 571155 | 64.0 | 6.86 | 0.68 |
| | 2750 | | | | | | | |
| | (PZO: 250) | | | | | | | |
| 06 | PZT/PZO | 97.08 | 551449 | 103.85 | 761237 | 72.4 | 6.77 | 0.66 |
| | 4400 | | | | | | | |
| | (PZO: 400) | | | | | | | |
| 07 | 1000 | 99.16 | 66026 | 104.06 | 754870 | 8.8 | 4.9 | 0.78 |
| 08 | 2500 | 99.1 | 101873 | 103.91 | 1892329 | 5.7 | 4.81 | 1.53 |
| 09 | 4000 | 98.97 | 135667 | 103.73 | 2442262 | 5.5 | 4.76 | 1.00 |

Samples 1 to 6 shown in Table 2 each correspond to the sample according to Example 2, and have the film structure illustrated in FIG. 8. Samples 7 to 9 shown in Table 2 each correspond to the sample according to Comparative Example, and have the film structure illustrated in FIG. 9. The thickness of the PZO film 16 of each of Samples 1 to 6 and the thickness of the PZT film 17 of each of Samples 4 to 9 are as follows.

| | Thickness of | Thickness of |
|---|---|---|
| | PZO film 16 | PZT film 17 |
| Sample 1 (Example): | 50 nm | None |
| Sample 2 (Example): | 250 nm | None |
| Sample 3 (Example): | 400 nm | None |
| Sample 4 (Example): | 50 nm | 1000 nm (total |
| | | thickness: 1050 nm) |
| Sample 5 (Example): | 250 nm | 2500 nm (total |
| | | thickness: 2750 nm) |
| Sample 6 (Example): | 400 nm | 4000 nm (total |
| | | thickness: 4400 nm) |
| Sample 7 (Comparative Example): | None | 1000 nm |
| Sample 8 (Comparative Example): | None | 2500 nm |
| Sample 9 (Comparative Example): | None | 4000 nm |

The XRD data of each of Samples 1 to 9 is acquired, and the detail data taken out from the XRD data is shown in Table 2.

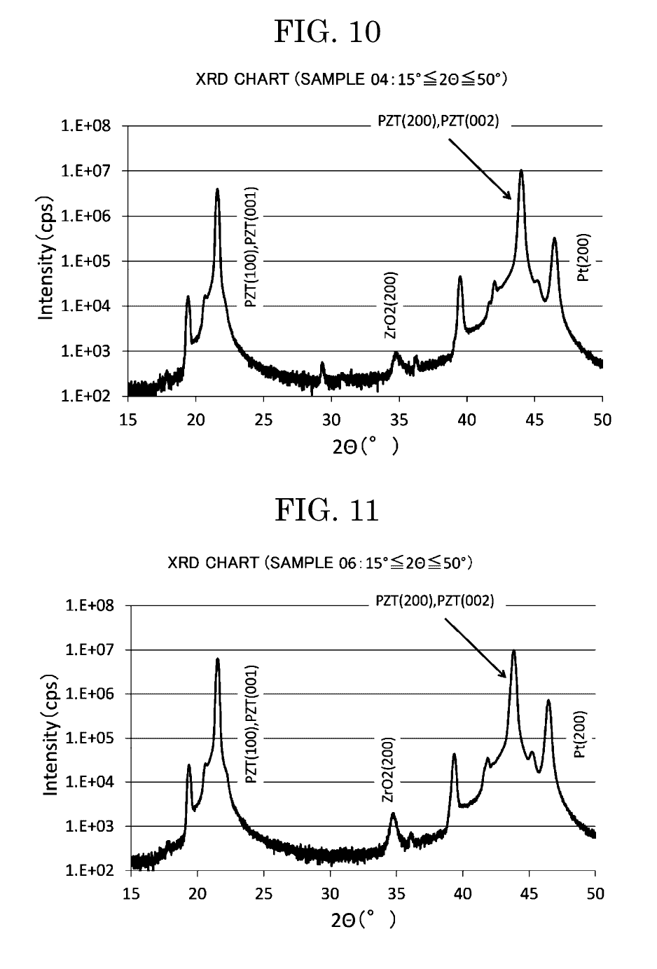

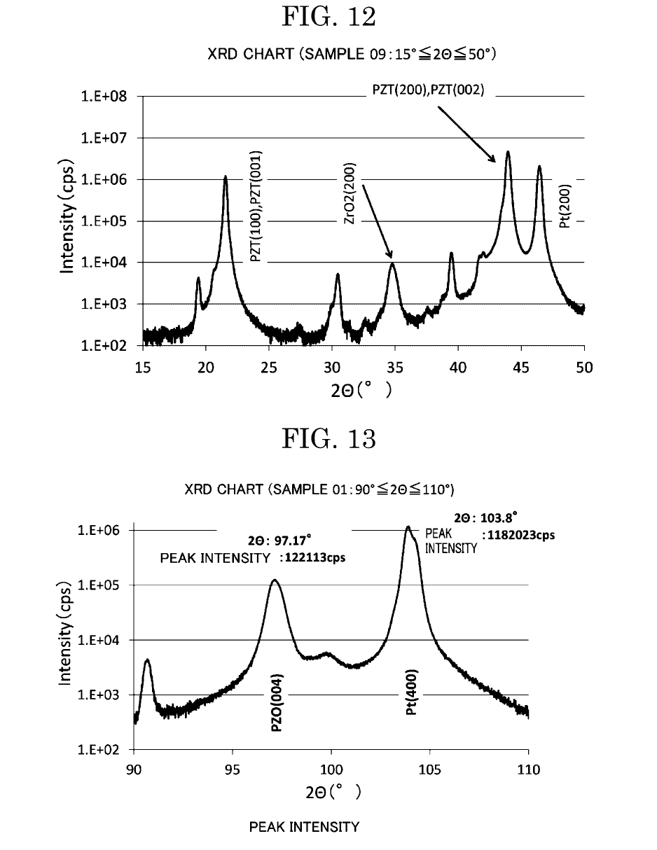

FIG. 10 illustrates an XRD chart of Sample 4 (Example), FIG. 11 illustrates an XRD chart of Sample 6 (Example), and FIG. 12 illustrates an XRD chart of Sample 9 (Comparative Example). FIGS. 10 to 12 each illustrate the range of 15°≦2θ≦50°.

As illustrated in FIGS. 10 to 12, almost no difference in crystallinity in the range of 2θ≦50° is observed in all of Samples 4, 6 and 9, and all Samples are good PZT crystal films.

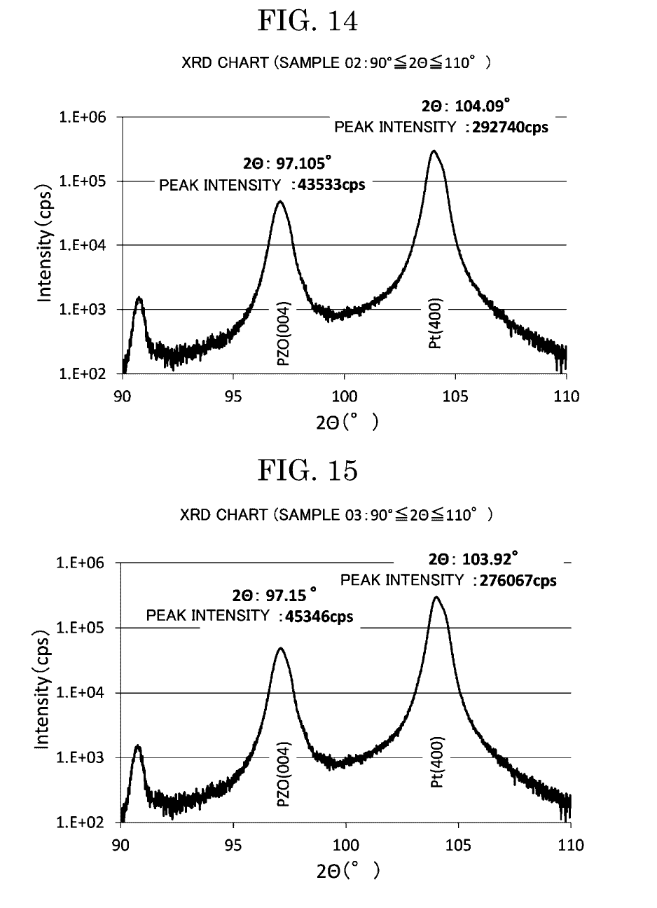

FIG. 13 illustrates an XRD chart of Sample 1 (Example), FIG. 14 illustrates an XRD chart of Sample 2 (Example), and FIG. 15 illustrates an XRD chart of Sample 3 (Example). FIGS. 13 to 15 each illustrate the range of 90°≦2θ≦110°.

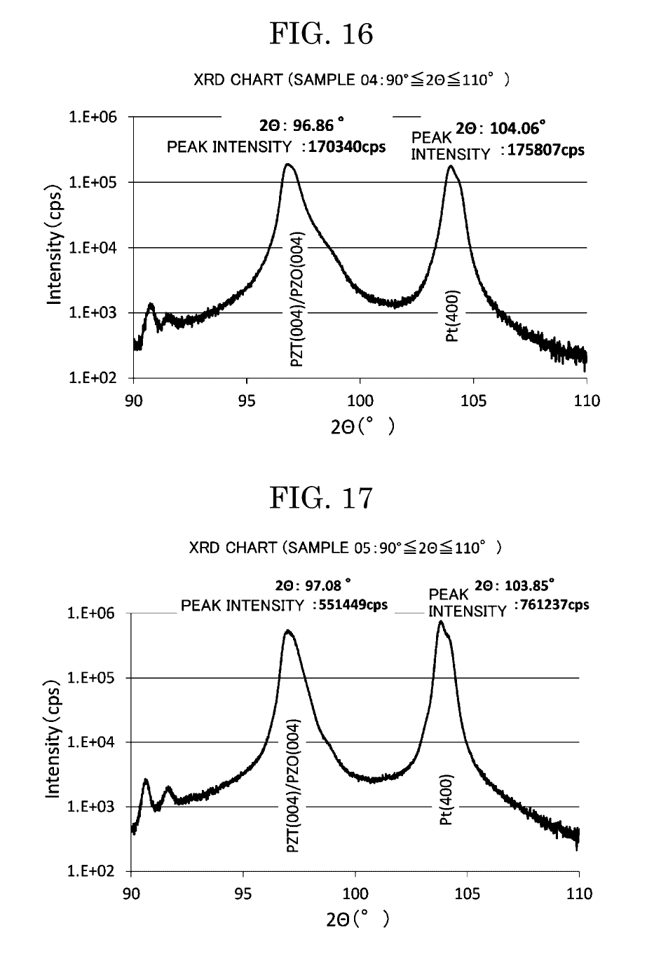

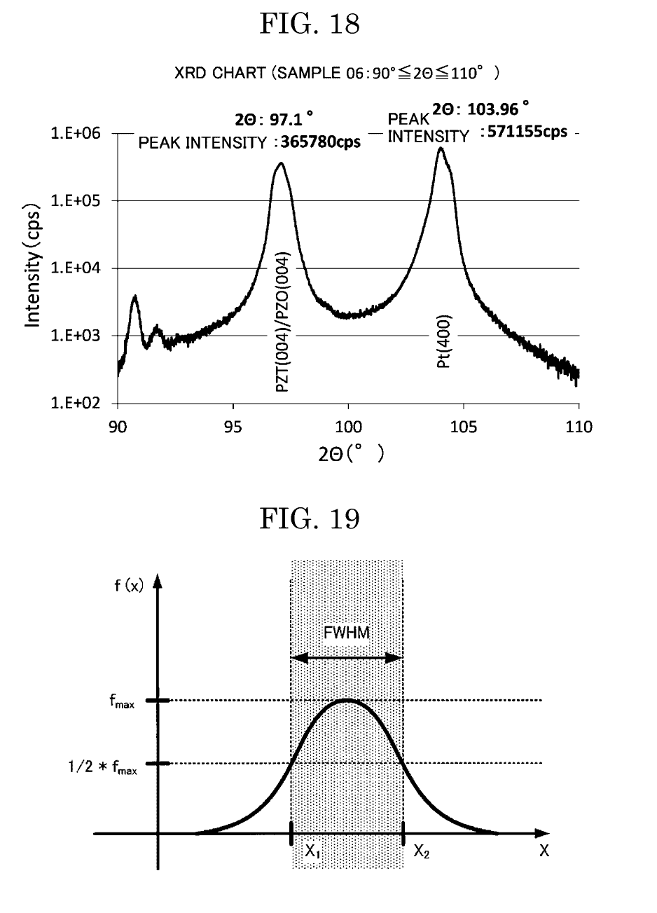

FIG. 16 illustrates an XRD chart of Sample 4 (Example), FIG. 17 illustrates an XRD chart of Sample 5 (Example), and FIG. 18 illustrates an XRD chart of Sample 6 (Example). FIGS. 16 to 18 each illustrate the range of 90°≦2θ≦110°.

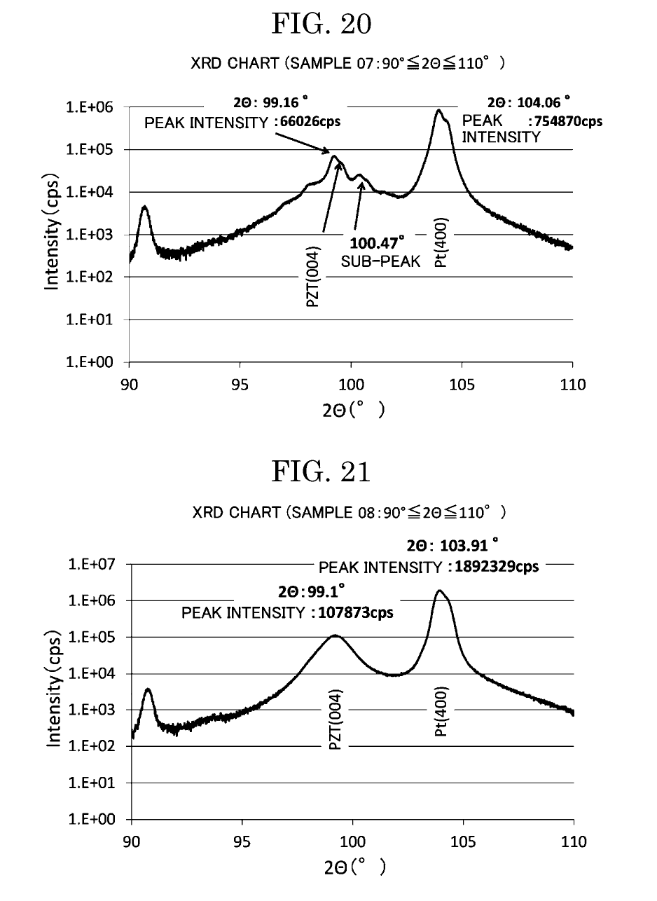

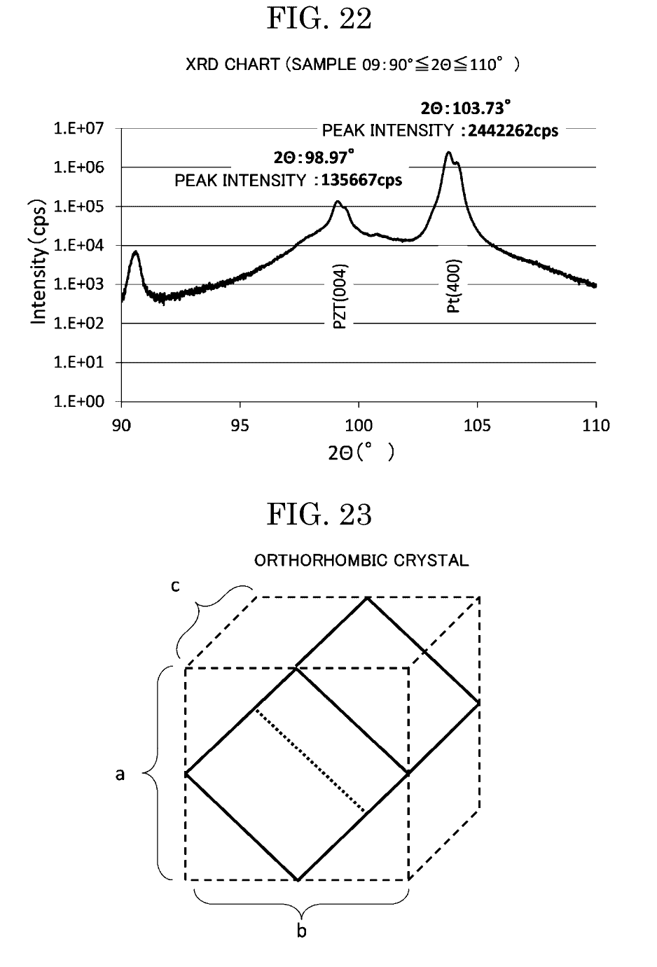

FIG. 20 illustrates an XRD chart of Sample 7 (Comparative Example), FIG. 21 illustrates an XRD chart of Sample 8 (Comparative Example), and FIG. 22 illustrates an XRD chart of Sample 9 (Comparative Example). FIGS. 20 to 22 each illustrate the range of 90°≦2θ≦110°.

In Samples 1 to 3 (Examples), the (004) peak was present in a very low angle region of 2θ≦97° as illustrated in FIGS. 13 to 15, in all cases where the PZO film 16 as the initial nucleus had a thickness of 50 to 400 nm. Additionally, also in Samples 4 to 6 (Examples) in which a PZT (55/45) film 17 was formed onto the PZO film 16 as the initial nucleus so as to have a thickness of 1000 to 4000 nm, the (004) peak was present in a very low angle region of 2θ≦97° as illustrated in FIGS. 16 to 18. In addition, as shown in Table 2, in Samples 4 to 6 (Examples), the intensity of the (004) peak of PZT was 175000 cps or more per 1000 nm in thickness, and the crystallinity was found to be very good. Furthermore, as shown in Table 2, the intensity ratio of the peaks, PZT (004)/Pt (400) was found to be (004)/(400)>60% in Samples 4 to 6 (Examples). Moreover, as shown in Table 2, the difference in 2θ between the lengths of ac-axes, |(400)−(004)|, was as very large as |(400)−(004)|>6.5° in Samples 4 to 6 (Examples), and thus it was sufficiently expected that the residual polarization value was large.

In addition, as shown in Table 2, in Samples 4 to 6 (Examples), the full width at half maximum FWHM, so-called, the half-value width satisfied FWHM<0.8°, which exhibited the numerical value equal to that of a single crystal. The full width at half maximum (FWHM) herein means the width illustrated in FIG. 19 (“half-value width” in Wikipedia).

In addition, when Samples 4 to 6 (Examples) are compared with Samples 7 to 9 (see FIGS. 20 to 22) according to Comparative Examples produced by the manufacturing method illustrated in FIG. 9, it can be seen that the PZT film of each of Samples 4 to 6 (Examples) is an excellent crystal film.

According to the present Example, it is possible to obtain a (001) c-axis singly oriented PZT film, and thereby to improve a piezoelectric property of the PZT film, by using the PZO film as the initial nuclear layer (namely, buffer layer) of the PZT film.

### Example 3

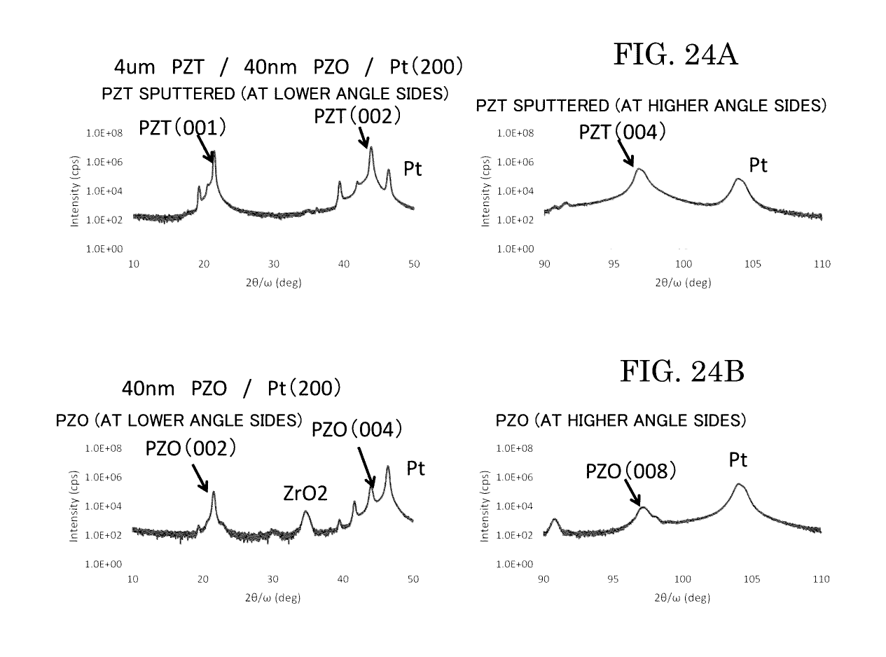

A Si substrate, a ZrO₂ film and a Pt film were produced by the similar methods to those in the sample according to Example 1. A PZO precursor solution (the same solution as in each of Examples 1 and 2) was then coated on the Pt film under rotation conditions of 5000 rpm and 10 seconds by a spin-coating method so that PZO having a thickness of 40 nm was obtained. After that, crystallization was conducted at a temperature raising rate of 10° C./sec, in a sintering environment of O₂ and 10 atm, and at a sintering temperature of 650° C. for 1 minute. Thereafter, the XRD diffraction was evaluated and it was found that there was obtained a PZO film having a thickness of 40 nm, oriented in (001) as in FIG. 24B.

Next, a PZT film having a thickness of 4 μm was subsequently formed on the PZO film having a thickness of 40 nm by a sputtering method. It was found from the XRD pattern that there was able to be obtained a PZT (Zr/Ti=55/45: value by XRF analysis) film having a thickness of 4 μm while having the lattice constants equivalent to the lattice constants of the PZO film oriented in (001), namely, while keeping the length of the c-axis of PZO, as illustrated in FIG. 24A.

In a case of the PZO film having a thickness of 40 nm in FIG. 24B, when the PZT film having a thickness of 4 μm in FIG. 24A was coated on ZrO₂ the presence of which was able to be clearly confirmed, the intensity of PZT was significantly high when the thickness of the PZT film was as large as 4 μm, and the presence of ZrO₂ was not able to be confirmed any more in a case of the XRD evaluation conditions regardless of the same substrate.

### REFERENCE SIGNS LIST

11: Si substrate
12: ZrO₂ film
13: Pt film
14: Sr(Ti_{0.8}Ru_{0.2})O₃ film (STRO film)
15: laminated film with PbZrO₃ film (PZO film) and Pb(Zr_{0.55}Ti_{0.45})O₃ film (PZT film) being sequentially laminated
16: PZO film
17: Pb(Zr_{0.55}Ti_{0.45})O₃ film (PZT film)
103: lower electrode
104: PbZrO₃ film (PZO film)
105: PZT film
106: oxide film

1. Ferroelectric ceramics comprising:
a Pb(Zr_{1-A}Ti_{A})O₃ film; and
a Pb(Zr₁₋ₓTiₓ)O₃ film formed on said Pb(Zr_{1-A}Ti_{A})O₃ film; wherein
said A and x satisfy the following Formulae 1 to 3:
0≦A≦0.1 Formula 1
0.1<x<1 Formula 2
A<x Formula 3.

2. The ferroelectric ceramics according to claim 1, wherein
said A is 0, and
said Pb(Zr_{1-A}Ti_{A})O₃ film is a PbZrO₃ film.

3. The ferroelectric ceramics according to claim 1, wherein
said Pb(Zr_{1-A}Ti_{A})O₃ film is formed on an oxide film.

4. The ferroelectric ceramics according to claim 3, wherein
said oxide film is a Sr(Ti,Ru)O₃ film.

5. The ferroelectric ceramics according to claim 1, wherein
said Pb(Zr_{1-A}Ti_{A})O₃ film is formed on an electrode film.

6. The ferroelectric ceramics according to claim 5, wherein
said electrode film is made of an oxide or a metal.

7. The ferroelectric ceramics according to claim 5, wherein
said electrode film is a Pt film or an Ir film.

8. The ferroelectric ceramics according to claim 5, wherein
said electrode film is formed on a ZrO₂ film.

9. The ferroelectric ceramics according to claim 5, wherein
said electrode film is formed on a Si substrate.

10. A manufacturing method of ferroelectric ceramics for forming a Pb(Zr₁₋ₓTiₓ)O₃ film on a Pb(Zr_{1-A}Ti_{A})O₃ film, wherein
said A and x satisfy the following Formulae 1 to 3:
0≦A≦0.1 Formula 1
0.1<x<1 Formula 2
A<x Formula 3.

11. The manufacturing method of ferroelectric ceramics according to claim 10, wherein
said A is 0, and
said Pb(Zr_{1-A}Ti_{A})O₃ film is a PbZrO₃ film.

12. The manufacturing method of ferroelectric ceramics according to claim 10, wherein
said Pb(Zr_{1-A}Ti_{A})O₃ film is formed by coating a Pb(Zr_{1-A}Ti_{A})O₃ precursor solution on a substrate, and performing crystallization in an oxygen atmosphere at 5 atm or more.
